(19) United States
(12) Patent Application Publication
(10) Pub. No.: US 2002/0006029 A1
(43) Pub. Date: Jan. 17, 2002

(54) Electronic device with heat-dissipating unit

(76) Inventor: Yi-Loh Liu, Taipei Hsien (TW)

Correspondence Address: Kenneth C. Winterton, SHERIDAN ROSS P.C., Suite 1200, 1560 Broadway, Denver, CO, 80202-5141, US

(21) Appl. No.: 09/777,542

(22) Filed: Feb. 6, 2001

(30) Foreign Application Priority Data
Jul. 13, 2000 (TW) 089212077

(51) Int. Cl. H05K 7/20

(52) U.S. Cl. 361/702

(57) ABSTRACT

An electronic device includes a connector-mounting side wall, a main circuit board and a heat-dissipating unit. The connector-mounting side wall is formed with a set of connector-mounting holes adapted to be mounted with electrical connectors, and a vent hole. The main circuit board has one edge disposed adjacent to the connector-mounting side wall, and is provided with a heat-generating electronic component. The heat-dissipating unit includes a heat sink, a heat-conducting plate and a heat-exchanger pipe. The heat sink is mounted on the connector-mounting side wall adjacent to the vent hole. The heat-conducting plate is disposed on the main circuit board so as to contact a heat-dissipating side of the electronic component. The heat-exchanger pipe has a first end connected to the heat-conducting plate, and a second end opposite to the first end and mounted on the heat sink for transmitting heat from the heat-conducting plate to the heat sink.

### BACKGROUND OF THE INVENTION

1. Field of the Invention

The invention relates to an electronic device, more particularly to an electronic device with a heat-dissipating unit that can achieve enhanced heat dissipation economically.

2. Description of the Related Art

The trend of recent developments of notebook computers is toward increased operational speed of central processing units, more and better functions, and reduced size. However, increased operational speed of the central processing unit entails the problem of dissipation of increased heat generated by the central processing unit during operation without incurring additional costs.

### SUMMARY OF THE INVENTION

Therefore, the main object of the present invention is to provide an electronic device with a heat-dissipating unit that can achieve enhanced heat dissipation economically.

Accordingly, the electronic device of this invention includes a connector-mounting side wall, a main circuit board and a heat-dissipating unit. The connector-mounting side wall is formed with a set of connector-mounting holes adapted to be mounted with electrical connectors, and a vent hole. The main circuit board has one edge disposed adjacent to the connector-mounting side wall, and is provided with a heat-generating electronic component. The heat-dissipating unit includes a heat sink, a heat-conducting plate and a heat-exchanger pipe. The heat sink is mounted on the connector-mounting side wall adjacent to the vent hole. The heat-conducting plate is disposed on the main circuit board so as to contact a heat-dissipating side of the electronic component. The heat-exchanger pipe has a first end connected to the heat-conducting plate, and a second end opposite to the first end and mounted on the heat sink for transmitting heat from the heat-conducting plate to the heat sink.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of the preferred embodiment of an electronic device according to the present invention;

FIG. 2 is a perspective view of an assembly of a connector-mounting side wall and a heat-dissipating unit of the preferred embodiment;

FIG. 3 is a rear bottom perspective view of the assembly of FIG. 2; and

FIG. 4 is a perspective view of the preferred embodiment prior to mounting of a heat-conducting plate and a heat-exchanger pipe.

### DETAILED DESCRIPTION OF THE PREFERRED EMBODIMENT

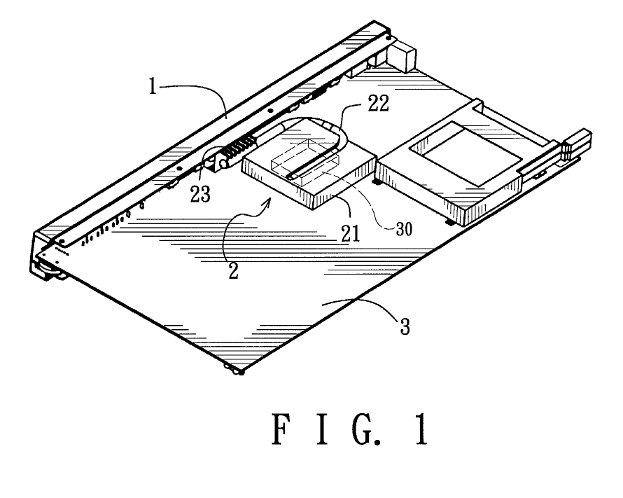

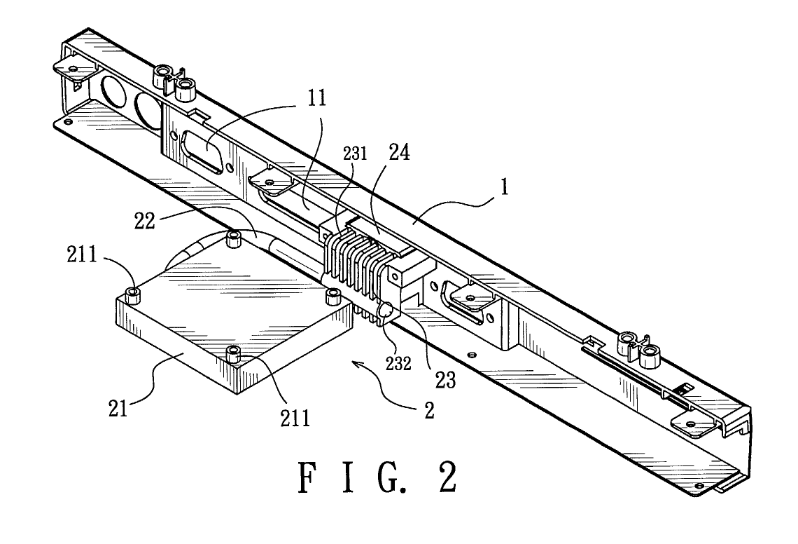

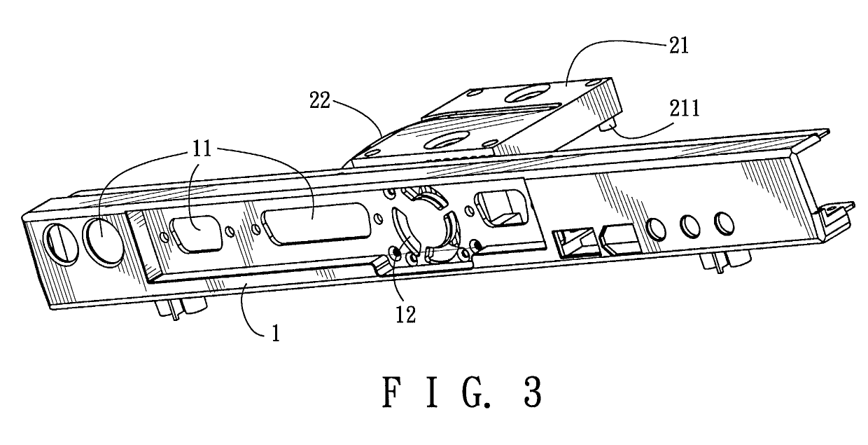

Referring to FIGS. 1 to 4, an electronic device according to the present invention is to be embodied in a notebook computer (not shown) and is shown to include a connector-mounting side wall 1, a main circuit board 2 and a heat-dissipating unit 3.

The connector-mounting side wall 1 forms a part of a housing of the notebook computer, and is formed with a set of connector-mounting holes 11 adapted to be mounted with electrical connectors (not shown), and a vent hole 12. The connector-mounting side wall 1 is preferably made from a magnesium-aluminum alloy that has good heat conductivity.

The main circuit board 3 has a rear edge mounted on the connector-mounting side wall 1, and is provided with a heat-generating electronic component 30, such as a central processing unit.

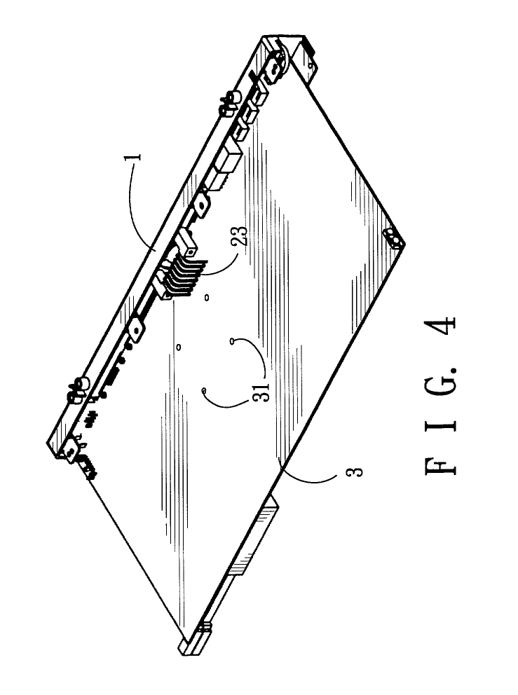

The heat-dissipating unit 2, which is preferably made from a magnesium-aluminum alloy, includes a heat sink 23, a heat-conducting plate 21 and a heat-exchanger pipe 22. The heat sink 23 is mounted on the connector-mounting side wall 1 adjacent to the vent hole 12. The heat-conducting plate 21 is disposed on the main circuit board 3 so as to contact a heat-dissipating side of the electronic component 30. The heat-exchanger pipe 22 has a first end connected to the heat-conducting plate 21, and a second end opposite to the first end and mounted on the heat sink 23 for transmitting heat from the heat-conducting plate 21 to the heat sink 23. The heat-conducting plate 21 is formed with a plurality of retaining protrusions 211. The main circuit board 3 is formed with a plurality of retaining holes 31 (see FIG. 4) for engaging the retaining protrusions 211 so as to retain the heat-conducting plate 21 on the main circuit board 3. The heat sink 23 includes a stack of spaced-apart fin plates 231 which are formed with aligned holes. The second end of the heat-exchanger pipe 22 extends through the aligned holes 232 in the fin plates 231 to transfer the heat from the heat-dissipating plate 21 to the fin plates 231. Preferably, the heat sink 23 is formed integrally with the connector-mounting side wall 1.

The heat-dissipating unit 2 further includes a heat-dissipating fan 24 mounted on the connector-mounting side wall 1 between the heat sink 23 and the vent hole 12 to enhance dissipation of heat.

In use, since the heat sink 23 is mounted on the connector-mounting side wall 1, which has a relatively large area of contact with the ambient air, the heat-dissipating effect is vastly improved. Furthermore, compared with the prior art that utilizes connector-mounting frames which are punched from pig iron and which are therefore relatively heavy, the connector-mounting side wall 1 has the advantage of being light-weight without incurring increased costs.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. An electronic device comprising:
a connector-mounting side wall formed with a set of connector-mounting holes adapted to be mounted with electrical connectors, and a vent hole;
a main circuit board having one edge disposed adjacent to said connector-mounting side wall, said main circuit board being provided with a heat-generating electronic component; and
a heat-dissipating unit which includes
a heat sink mounted on said connector-mounting side wall adjacent to said vent hole,
a heat-conducting plate disposed on said main circuit board so as to contact a heat-dissipating side of said electronic component, and
a heat-exchanger pipe having a first end connected to said heat-conducting plate and a second end opposite to said first end and mounted on said heat sink for transmitting heat from said heat-conducting plate to said heat sink.

2. The electronic device as claimed in claim 1, wherein said heat-conducting plate is formed with a plurality of retaining protrusions, said main circuit board being formed with a plurality of retaining holes for engaging said retaining protrusions so as to retain said heat-conducting plate on said main circuit board.

3. The electronic device as claimed in claim 1, wherein said heat sink includes a stack of spaced-apart fin plates which are formed with aligned holes, said second end of said heat-exchanger pipe extending through said aligned holes in said fin plates.

4. The electronic device as claimed in claim 1, wherein said heat sink is formed integrally with said connector-mounting side wall.

5. The electronic device as claimed in claim 1, wherein said heat-dissipating unit and said connector-mounting side wall are each made from a magnesium-aluminum alloy.

6. The electronic device as claimed in claim 1, wherein said heat-dissipating unit further includes a heat-dissipating fan mounted on said connector-mounting side wall between said heat sink and said vent hole.
